(19) United States
(12) Patent Application Publication
(10) Pub. No.: US 2023/0228875 A1
(43) Pub. Date: Jul. 20, 2023

(54) SOLID-STATE IMAGING ELEMENT, SENSING SYSTEM, AND CONTROL METHOD OF SOLID-STATE IMAGING ELEMENT

(71) Applicants: SONY GROUP CORPORATION, TOKYO (JP); SONY SEMICONDUCTOR SOLUTIONS CORPORATION, KANAGAWA (JP)

(72) Inventors: KEI NAKAGAWA, TOKYO (JP); KATSUHIKO HANZAWA, KANAGAWA (JP); TAKAO TANIKAME, TOKYO (JP)

(21) Appl. No.: 17/996,271

(22) PCT Filed: Feb. 26, 2021
(86) PCT No.: PCT/JP2021/007411

§ 371 Date: Oct. 14, 2022

(30) Foreign Application Priority Data
Apr. 22, 2020 (JP) 2020-075881

(51) Int. Cl. G01S 17/14; G01S 7/4863; G01S 7/4865

(52) U.S. Cl. CPC G01S 17/14; G01S 7/4863; G01S 7/4865

(57) ABSTRACT

In a solid-state imaging element that measures a distance, a circuit scale is reduced. The solid-state imaging element includes a pulse signal generation section and an up-down counter. The pulse signal generation section is provided with an avalanche photodiode that converts incident light including reflected light of irradiation light radiated during a predetermined light-on period into a photocurrent and multiplies the photocurrent and a quench circuit that generates a pulse signal on the basis of the multiplied photocurrent. The up-down counter performs one of up counting and down counting each time the pulse signal is generated during the light-on period, and performs another of the up counting and the down counting each time the pulse signal is generated during a light-off period that does not correspond to the light-on period.

### TECHNICAL FIELD

The present technology relates to a solid-state imaging element. Specifically, the present technology relates to a solid-state imaging element that performs photon counting, a sensing system, and a control method of the solid-state imaging element.

### BACKGROUND ART

In recent years, a device called a single photon avalanche diode (SPAD) that captures very weak optical signals and implements optical communication, distance measurement, photon counting, and the like has been developed and studied. The SPAD is an avalanche photodiode whose sensitivity is high enough to detect one photon. For example, a solid-state imaging element in which a circuit that detects photons by using a SPAD and a counter that counts the number of photons during an exposure period are arrayed for every pixel has been proposed (see, for example, Patent Document 1).

### CITATION LIST

### Patent Document

Patent Document 1: WO 2019/150785 A

### SUMMARY OF THE INVENTION

### Problems to be Solved by the Invention

The conventional technology described above aims to improve image quality when imaging is performed in a dark environment by detecting weak light by using a high sensitivity SPAD. However, the solid-state imaging element described above cannot measure the distance to an object. It is also possible to provide a plurality of counters that counts the number of photons at different timings for every pixel to perform distance measurement by a time of flight (ToF) method, but in this case, it is necessary to add counters for every pixel. In this manner, in the solid-state imaging element described above, there is a problem that the circuit scale increases when distance measurement is performed by the ToF method.

The present technology has been made in view of such a situation, and an object thereof is to reduce the circuit scale in a solid-state imaging element that measures a distance.

### Solutions to Problems

The present technology has been made to solve the above-described problems, and a first aspect thereof is a solid-state imaging element including: a pulse signal generation section that is provided with an avalanche photodiode that converts incident light including reflected light of irradiation light radiated during a predetermined light-on period into a photocurrent and multiplies the photocurrent and a quench circuit that generates a pulse signal on the basis of the above-described multiplied photocurrent; and an up-down counter that performs one of up counting and down counting each time the above-described pulse signal is generated during the above-described light-on period, and performs another of the above-described up counting and the above-described down counting each time the above-described pulse signal is generated during a light-off period that does not correspond to the above-described light-on period, and a control method thereof. Therefore, there is provided an effect in which the number of counters is reduced.

Furthermore, in the first aspect, the above-described irradiation light may include intermittent light. Therefore, there is provided an effect in which distance measurement is performed by the ToF method.

Furthermore, in the first aspect, the above-described up-down counter may include first and second up-down counters, the above-described first up-down counter may perform either the above-described up counting or the above-described down counting on the basis of a first clock signal having a phase difference of 0 degrees or 180 degrees from the above-described intermittent light, and the above-described second up-down counter may perform either the above-described up counting or the above-described down counting on the basis of a second clock signal having a phase difference of 90 degrees or 270 degrees from the above-described intermittent light. Therefore, there is provided an effect in which the distance is calculated from the respective count values of the two up-down counters.

Furthermore, in the first aspect, the above-described up-down counter may perform either the above-described up counting or the above on the basis of a predetermined clock signal, and a phase difference of the above-described clock signal with respect to the above-described intermittent light may be set to 0 degrees or 180 degrees during a first period, and set to 90 degrees or 270 degrees during a second period. Therefore, there is provided an effect in which the number of counters is further reduced.

Furthermore, in the first aspect, a logical sum gate that supplies a logical sum of the above-described pulse signal of each of a plurality of pixels to the above-described up-down counter may be further included, and the above-described pulse signal generation section may be arranged in each of the above-described plurality of pixels. Therefore, there is provided an effect in which the circuit scale per pixel is reduced.

Furthermore, in the first aspect, the above-described irradiation light may include structured light, and the above-described incident light may include the above-described reflected light and background light. Therefore, there is provided an effect in which distance measurement is performed by a structured illumination method.

Furthermore, in the first aspect, the above-described up-down counter may include: a first flip-flop to which the above-described pulse signal is input; a selector that selects either a non-inverted output signal or an inverted output signal of the above-described first flip-flop in accordance with a predetermined enable signal, and outputs the selected signal as a selection signal; and a second flip-flop to which the above-described selection signal is input. Therefore, therefore, there is provided an effect in which counting is performed by a counter using flip-flops.

Furthermore, in the first aspect, the above-described first and second flip-flops may include JK flip-flops, and the above-described pulse signal and the above-described selection signal may be input to clock terminals. Therefore, there is provided an effect in which counting is performed by a counter using JK flip-flops.

Furthermore, in the first aspect, the above-described first and second flip-flops may include D flip-flops, the above-described pulse signal and the above-described selection signal may be input to clock terminals, and the above-described inverted output signal of the above-described first flip-flop may be input to a delay terminal of the above-described first flip-flop. Therefore, there is provided an effect in which counting is performed by a counter using D flip-flops.

Furthermore, a second aspect of the present technology is a sensing system including: a light-emitting section that radiates irradiation light during a predetermined light-on period; a pulse signal generation section that is provided with an avalanche photodiode that converts incident light including reflected light of the above-described irradiation light into a photocurrent and multiplies the photocurrent and a quench circuit that generates a pulse signal on the basis of the above-described multiplied photocurrent; and an up-down counter that performs one of up counting and down counting each time the above-described pulse signal is generated during the above-described light-on period, and performs another of the above-described up counting and the above-described down counting each time the above-described pulse signal is generated during a light-off period that does not correspond to the above-described light-on period. Therefore, there is provided an effect in which the number of counters is reduced in a system that performs distance measurement.

### BRIEF DESCRIPTION OF DRAWINGS

FIG. 1 is a block diagram depicting a configuration example of a sensing system in a first embodiment of the present technology.

FIG. 2 is a view depicting an example of a stacked structure of a solid-state imaging element in the first embodiment of the present technology.

FIG. 3 is a block diagram depicting a configuration example of the solid-state imaging element in the first embodiment of the present technology.

FIG. 4 is a block diagram depicting a configuration example of a pixel in the first embodiment of the present technology.

FIG. 5 is a circuit diagram depicting a configuration example of a pulse signal generation section in the first embodiment of the present technology.

FIG. 6 is a view for describing an operation of an up-down counter in the first embodiment of the present technology.

FIG. 7 is a circuit diagram depicting a configuration example of the up-down counter in the first embodiment of the present technology.

FIG. 8 is a circuit diagram depicting a configuration example of a selector in the first embodiment of the present technology.

FIG. 9 is a timing chart depicting an example of an operation of the solid-state imaging element in the first embodiment of the present technology.

FIG. 10 is a block diagram depicting a configuration example of a pixel in a comparative example.

FIG. 11 is a flowchart depicting an example of an operation of the sensing system in the first embodiment of the present technology.

FIG. 12 is a circuit diagram depicting a configuration example of a pulse signal generation section in a first modification of the first embodiment of the present technology.

FIG. 13 is a circuit diagram depicting a configuration example of an up-down counter in a second modification of the first embodiment of the present technology.

FIG. 14 is a circuit diagram depicting a configuration example of a selector in the second modification of the first embodiment of the present technology.

FIG. 15 is a block diagram depicting a configuration example of a pixel in a second embodiment of the present technology.

FIG. 16 is a timing chart depicting an example of an operation of a solid-state imaging element in the second embodiment of the present technology.

FIG. 17 is a block diagram depicting a configuration example of a sensing system in a third embodiment of the present technology.

FIG. 18 is a timing chart depicting an example of an operation of a solid-state imaging element in the third embodiment of the present technology.

FIG. 19 is a plan view depicting a configuration example of a pixel array section in a fourth embodiment of the present technology.

FIG. 20 is a block diagram depicting a configuration example of a pixel block in the fourth embodiment of the present technology.

FIG. 21 is a block diagram depicting an example of a schematic configuration of a vehicle control system.

FIG. 22 is an explanatory diagram depicting an example of the installation position of an imaging section.

### MODE FOR CARRYING OUT THE INVENTION

Hereinafter, modes for carrying out the present technology (hereinafter referred to as embodiments) will be described. The description will be given in the following order.

1. First embodiment (example of counting the number of photons by up-down counters)

2. Second embodiment (example of counting the number of photons by up-down counter with phases shifted in each of two frames)

3. Third embodiment (example of radiating structured light and counting the number of photons by up-down counter)

4. Fourth embodiment (example of counting the number of photons of pixel block by up-down counters)

5. Application example to mobile body

### 1. First Embodiment

[Configuration Example of Sensing System]

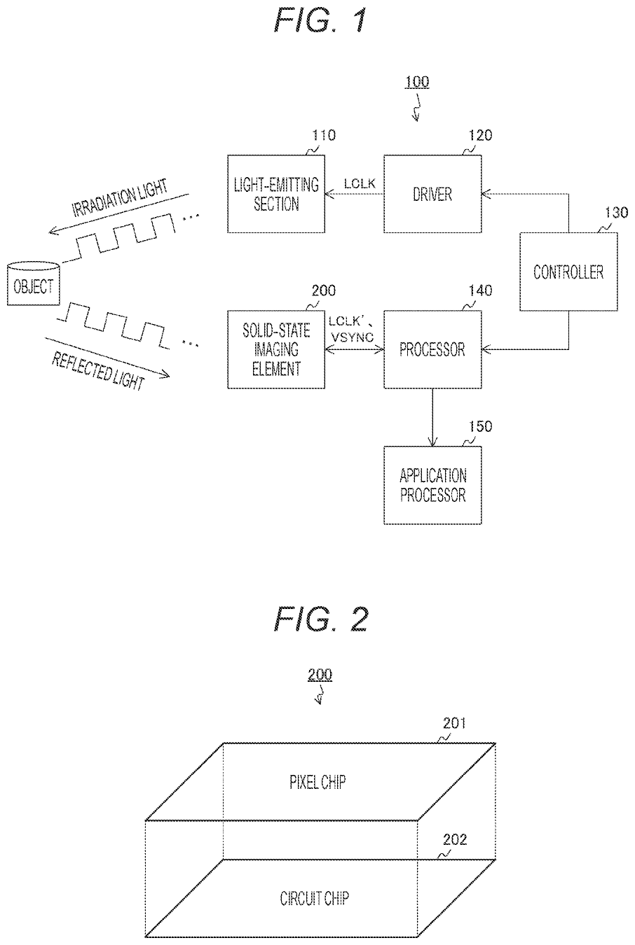

FIG. 1 is a block diagram depicting a configuration example of a sensing system 100 in a first embodiment of the present technology. The sensing system 100 includes a light-emitting section 110, a driver 120, s controller 130, a solid-state imaging element 200, a processor 140, and an application processor 150.

Each of the circuits and elements in the sensing system 100 may be arranged in one electronic device, or may be arranged in a distributed manner in a plurality of devices. In a case of being arranged in a distributed manner in a plurality of devices, for example, the light-emitting section 110, the driver 120, the controller 130, the solid-state imaging element 200, and the processor 140 are arranged in an imaging device, and the application processor 150 is arranged in an image processing device.

The light-emitting section 110 is one that emits light in accordance with a light emission control signal LCLK from the driver 120, and radiates intermittent light as irradiation light. For example, near-infrared light or the like is used as irradiation light.

The driver 120 is one that generates a predetermined cycle signal as the light emission control signal LCLK, and supplies the light emission control signal LCLK to the light-emitting section 110, under the control of the controller 130.

The controller 130 is one that makes the driver 120 and the processor 140 operate in synchronization with each other. The controller 130 makes the driver 120 generate the light emission control signal LCLK, and makes the processor 140 generate the same signal as the light emission control signal LCLK as a light emission control signal LCLK′. Furthermore, the controller 130 makes the processor 140 generate a vertical synchronization signal VSYNC.

Here, frequency of the vertical synchronization signal VSYNC is, for example, 30 hertz (Hz) or 60 hertz (Hz). On the other hand, frequency of the light emission control signal LCLK is higher than that of the vertical synchronization signal VSYNC, and is, for example, 10 to 20 megahertz (MHz).

The processor 140 is one that controls the solid-state imaging element 200 and the application processor 150. The processor 140 generates the light emission control signal LCLK′ and the vertical synchronization signal VSYNC, and supplies the light emission control signal LCLK′ and the vertical synchronization signal VSYNC to the solid-state imaging element 200. Furthermore, the processor 140 receives a depth map from the solid-state imaging element 200, and supplies the depth map to the application processor 150.

The application processor 150 is one that performs predetermined processing such as image recognition processing and the like on the basis of the depth map.

The solid-state imaging element 200 is one that generates a depth map by photoelectric conversion. The solid-state imaging element 200 photoelectrically converts incident light including reflected light of the irradiation light in synchronization with the light emission control signal LCLK′ to generate a depth map, and supplies the depth map to the processor 140.

Note that the solid-state imaging element 200 may include some or all of the functions of the processor 140 and the application processor 150.

[Configuration Example of Solid-State Imaging Element]

FIG. 2 is a view depicting an example of a stacked structure of the solid-state imaging element 200 in the first embodiment of the present technology. The solid-state imaging element 200 includes a circuit chip 202 and a pixel chip 201 stacked on the circuit chip 202. These chips are electrically connected with each other through a connection portion such as a via or the like. Note that the connection can also be made by Cu—Cu bonding or a bump in addition to the via. The connection can also be made by these other methods (magnetic coupling or the like). Furthermore, although two chips are stacked, three or more layers can be stacked.

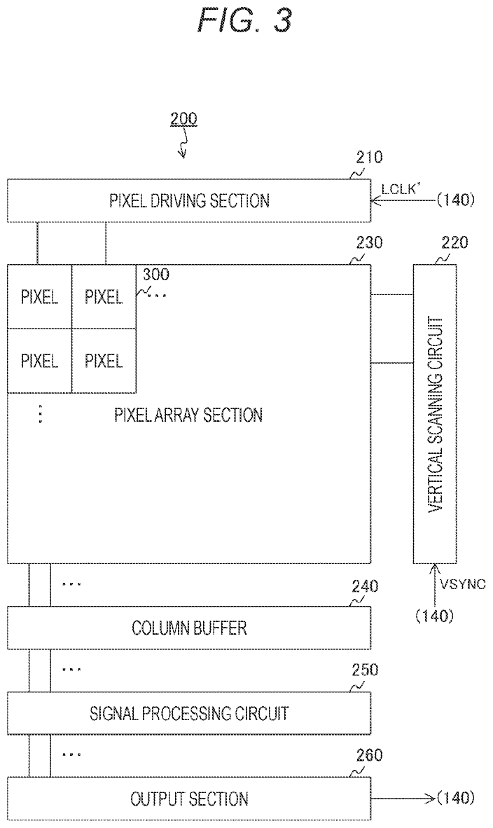

FIG. 3 is a block diagram depicting a configuration example of the solid-state imaging element 200 in the first embodiment of the present technology. The solid-state imaging element 200 includes a pixel driving section 210, a vertical scanning circuit 220, a pixel array section 230, a column buffer 240, a signal processing circuit 250, and an output section 260. Furthermore, a plurality of pixels 300 is arrayed in the pixel array section 230 in a two-dimensional grid shape.

The pixel driving section 210 is one that drives the pixels 300 in the pixel array section 230 in synchronization with the light emission control signal LCLK′, and makes the pixels 300 perform counting of the number of pulses.

The vertical scanning circuit 220 is one that sequentially selects the rows of the pixels 300 in synchronization with the vertical synchronization signal VSYNC, and makes the pixels 300 output the count values to the column buffer 240.

The column buffer 240 is one that holds the count value for every pixel.

The signal processing circuit 250 is one that performs predetermined signal processing with respect to data in which the count values are arrayed. For example, the signal processing circuit 250 obtains a distance on the basis of the count value for every pixel 300, generates a depth map in which data of these distances are arrayed, and supplies the depth map to the processor 140.

[Configuration of Pixel]

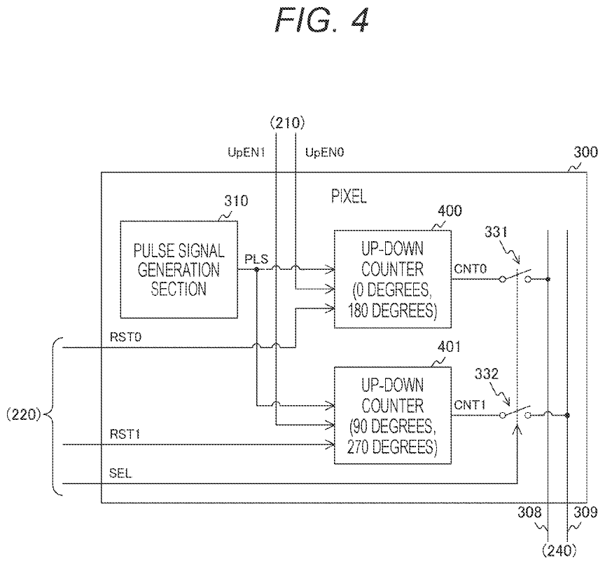

FIG. 4 is a block diagram depicting a configuration example of the pixel 300 in the first embodiment of the present technology. The pixel 300 includes a pulse signal generation section 310, up-down counters 400 and 401, and switches 331 and 332.

The pulse signal generation section 310 is one that photoelectrically converts incident light including reflected light of irradiation light to generate a pulse signal PLS. The pulse signal generation section 310 supplies the generated pulse signal PLS to the up-down counters 400 and 401.

The up-down counter 400 is one that performs either up counting or down counting on the basis of an up enable signal UpEN0 from the pixel driving section 210 each time the pulse signal PLS is generated. Here, the up enable signal UpEN0 is a signal that indicates either the up counting or the down counting. A clock signal having a phase difference of 0 degrees or 180 degrees (for example, 0 degrees) from the irradiation light (that is, the intermittent light) is used as the up enable signal UpEN0.

Furthermore, for example, in a case where the up enable signal UpEN0 is at a high level, enable is set, and the up-down counter 400 performs up counting. On the other hand, in a case where the up enable signal UpEN0 is at a low level, disable is set, and the up-down counter 400 performs down counting. The phase difference of the up enable signal UpEN0 is 0 degrees or 180 degrees (0 degrees or the like) as described above. Therefore, one (up counting or the like) of the up counting and the down counting is executed during a light-on period of the light-emitting section 110, and the other (down counting or the like) of the up counting and down counting is executed during a light-off period.

The up-down counter 401 is one that performs either up counting or down counting on the basis of an up enable signal UpEN1 from the pixel driving section 210 each time the pulse signal PLS is generated. Here, the up enable signal UpEN1 is a signal that indicates either the up counting or the down counting, and a clock signal having a phase difference of 90 degrees or 270 degrees (for example, 90 degrees) from the irradiation light is used as the up enable signal UpEN1.

For example, in a case where the up enable signal UpEN1 is at a high level, the up-down counter 400 performs up counting, and in a case where the up enable signal UpEN1 is at a low level, the up-down counter 400 performs down counting.

Furthermore, a count value CNT0 of the up-down counter 400 is initialized by a reset signal RST0 from the vertical scanning circuit 220. A count value CNT1 of the up-down counter 401 is initialized by a reset signal RST1 from the vertical scanning circuit 220.

Note that the up-down counter 400 is an example of a first up-down counter described in claims, and the up-down counter 401 is an example of a second up-down counter described in the claims.

The switch 331 is one that outputs the count value CNT0 to the column buffer 240 through a vertical signal line 308 in accordance with a selection signal SEL from the vertical scanning circuit 220. The switch 332 is one that outputs the count value CNT1 to the column buffer 240 through a vertical signal line 309 in accordance with the selection signal SEL from the vertical scanning circuit 220. In the pixel array section 230, two vertical signal lines 308 and 309 are wired for every column.

[Configuration Example of Pulse Signal Generation Section]

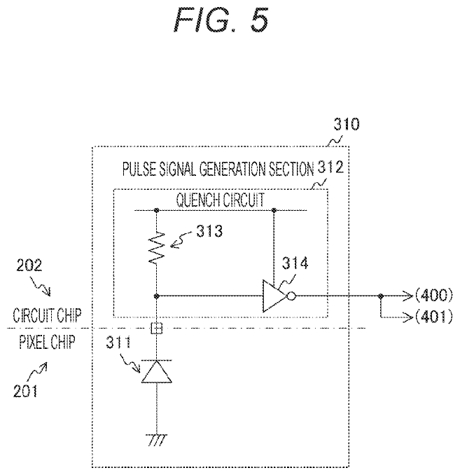

FIG. 5 is a circuit diagram depicting a configuration example of the pulse signal generation section 310 in the first embodiment of the present technology. The pulse signal generation section 310 includes a SPAD 311 and a quench circuit 312.

The SPAD 311 is one that generates a photocurrent by photoelectric conversion, and performs avalanche amplification. The quench circuit 312 is one that generates a pulse signal PLS on the basis of the multiplied photocurrent. The quench circuit 312 includes a resistor 313 and an inverter 314. Note that the SPAD 311 is an example of an avalanche photodiode described in the claims.

The resistor 313 and the SPAD 311 are connected in series between a power supply terminal and a ground terminal. The inverter 314 is one that inverts the potential at the connection point between the resistor 313 and the SPAD 311, and outputs the inverted potential to the up-down counters 400 and 401 as a pulse signal PLS.

Furthermore, for example, the SPAD 311 is provided in the pixel chip 201, and the resistor 313 and the inverter 314, and circuits (the up-down counter 400 and the like) at the subsequent stage are provided in the circuit chip 202. Note that the entire pulse signal generation section 310 can also be provided in the pixel chip 201.

[Configuration Example of Up-Down Counter]

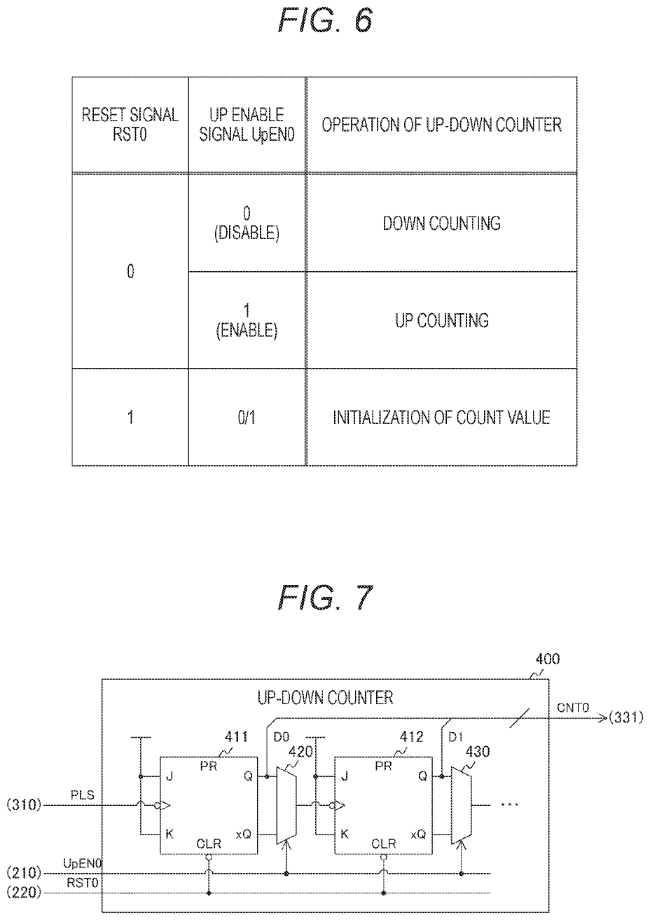

FIG. 6 is a view for describing an operation of the up-down counter 400 in the first embodiment of the present technology. In a case where the reset signal RST0 is at a low level, and the up enable signal UpEN0 is at a low level (that is, disable), the up-down counter 400 performs down counting.

In a case where the reset signal RST0 is at a low level, and the up enable signal UpEN0 is at a high level (that is, enable), the up-down counter 400 performs up counting. Furthermore, in a case where the reset signal RST0 is at a high level, the up-down counter 400 initializes the count value.

Note that an operation of the up-down counter 401 is similar to that of the up-down counter 400.

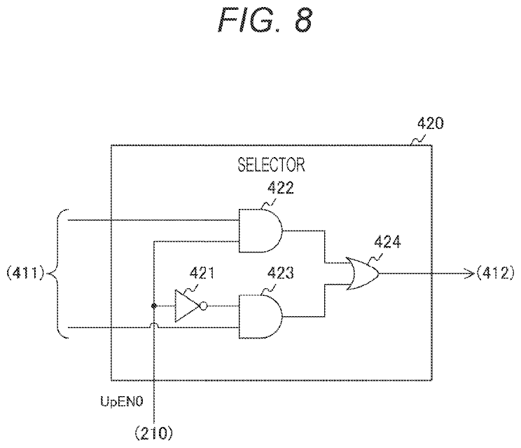

FIG. 7 is a circuit diagram depicting a configuration example of the up-down counter 400 in the first embodiment of the present technology. The up-down counter 400 includes a plurality of stages of JK flip-flops such as JK flip-flops 411, 412, and the like, and a predetermined number of stages of selectors such as selectors 420, 430, and the like. Assuming that the bit depth of a digital signal indicating the count value CNT0 is N (N being an integer), the number of stages of the number of stages of the JK flip-flops is N, and the number of stages of the selectors is N−1. Note that the JK flip-flops 411 and 412 are examples of first and second flip-flops described in the claims.

Each of the JK flip-flops is provided with a J terminal, a clock terminal, a K terminal, a CLR terminal, a Q terminal, and an xQ terminal. Each of the selectors is provided with two input terminals and one output terminal.

A high level is input to the J terminal and the K terminal of each of the JK flip-flops, and an inverted value of the reset signal RST0 from the vertical scanning circuit 220 is input to the CLR terminal. Furthermore, an inverted value of the pulse signal PLS from the pulse signal generation section 310 is input to the clock terminal of the JK flip-flop 411 of the first stage. A non-inverted output signal from the Q terminal of the JK flip-flop of the n-th stage and an inverted output signal from the xQ terminal of the JK flip-flop of the n-th stage are input to the selector of the n-th stage. Furthermore, the non-inverted output signal of the n-th stage is output to the switch 331 as the n-th bit data Dn of the digital signal indicating the count value CNT0.

The selector of the n-th stage selects either the non-inverted output signal or the inverted output signal of the JK flip-flop of the n-th stage in accordance with the up enable signal UpEN0. The selector of the n-th stage outputs the selected signal as a selection signal. The inverted value of the selection signal is input to the clock terminal of the JK flip-flop of the (n+1)-th stage.

Note that the circuit configuration of the up-down counter 401 is similar to that of the up-down counter 400. Furthermore, it is sufficient if the circuit configuration of the up-down counter 400 can implement the operation illustrated in FIG. 6, and the configuration is not limited to the circuit configuration illustrated in FIG. 7.

FIG. 8 is a circuit diagram depicting a configuration example of the selector 420 in the first embodiment of the present technology. The selector 420 includes an inverter 421, logical product (AND) gates 422 and 423, and a logical sum (OR) gate 424.

The AND gate 422 is one that outputs a logical product of the non-inverted output signal from the Q terminal of the JK flip-flop 411 and the up enable signal UpEN0 to the OR gate 424. The inverter 421 is one that inverts the up enable signal UpEN0 and outputs the inverted up enable signal UpEN0 to the AND gate 422.

The AND gate 423 is one that outputs a logical product of the inverted signal from the inverter 421 and the inverted output signal from the xQ terminal of the JK flip-flop 411 to the OR gate 424. The OR gate 424 is one that outputs a logical sum of the signals from the AND gates 422 and 423 to the clock terminal of the JK flip-flop 412 as a selection signal.

Note that the circuit configuration of the selector 430 is similar to that of the selector 420.

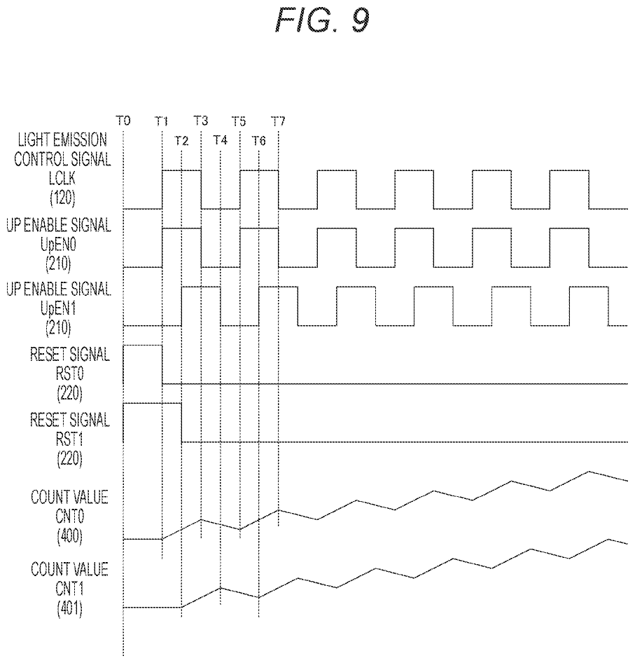

FIG. 9 is a timing chart depicting an example of an operation of the solid-state imaging element 200 in the first embodiment of the present technology. The pixel driving section 210 supplies the reset signal RST0 of a high level from an initialization timing T0 to a timing T1 at which the light emission control signal LCLK rises. Therefore, the count value CNT0 of the up-down counter 400 is initialized.

The light emission control signal LCLK is at a low level during a period from the timing T0 to T1, and is at a high level during a period from the timing T1 to T3. Furthermore, the light emission control signal LCLK is at a low level during a period from the timing T3 to T5, and is at a high level during a period from the timing T5 to T7. Hereinafter, the light emission control signal LCLK periodically fluctuates in a similar manner.

The pixel driving section 210 supplies a signal having a phase difference of 0 degrees from the light emission control signal LCLK to the pixel 300 as the up enable signal UpEN0.

The up-down counter 400 performs up counting with respect to the count value CNT0 every time the pulse signal PLS is input during a period from the timing T1 to T3 in which the up enable signal UpEN0 is at a high level. Furthermore, the up-down counter 400 performs down counting every time the pulse signal PLS is input during a period from the timing T3 to T5 in which the up enable signal UpEN0 is at a low level. Hereinafter, similarly, the up-down counter 400 performs up counting or down counting of the count value CNT0 in accordance with the up enable signal UpEN0.

Furthermore, the pixel driving section 210 supplies the reset signal RST0 of a high level from the timing T0 to the timing T2 at which the phase difference with respect to the timing T1 is 90 degrees. Therefore, the count value CNT1 of the up-down counter 401 is initialized.

The pixel driving section 210 supplies a signal having a phase difference of 90 degrees from the light emission control signal LCLK to the pixel 300 as the up enable signal UpEN1.

The up-down counter 401 performs up counting with respect to the count value CNT1 every time the pulse signal PLS is input during a period from the timing T2 to T4 in which the up enable signal UpEN1 is at a high level. Furthermore, the up-down counter 401 performs down counting every time the pulse signal PLS is input during a period from the timing T4 to T6 in which the up enable signal UpEN1 is at a low level. Hereinafter, similarly, the up-down counter 401 performs up counting or down counting of the count value CNT1 in accordance with the up enable signal UpEN1.

Note that the up-down counters 400 and 401 perform up counting when the up enable signal UpEN is at a high level, and perform down counting when the up enable signal UpEN is at a low level, but the configuration is not limited to this configuration. The up-down counters 400 and 401 can perform down counting when the up enable signal UpEN is at a high level, and can perform up counting when the up enable signal UpEN is at a low level.

The control described above is executed over a constant exposure period longer than a cycle of the light emission control signal LCLK. By this control, the up-down counter 400 performs up counting during a period in which the up enable signal UpEN0 (clock signal) having a phase difference of 0 degrees from the light emission control signal LCLK is at a high level. Furthermore, the up-down counter 400 performs down counting during a period in which the clock signal is at a low level. The count value of the down counting corresponds to the count value during a period in which the clock signal having the phase difference of 180 degrees from the light emission control signal LCLK is at a high level. Therefore, the count value CNT0 of the up-down counter 400 is a difference between a count value during a period in which the clock signal having the phase difference of 0 degrees is at a high level and a count value during a period in which the clock signal having the phase difference of 180 degrees is at a high level.

Similarly, the count value CNT1 of the up-down counter 401 is a difference between a count value during a period in which the clock signal having the phase difference of 90 degrees is at a high level and a count value during a period in which the clock signal having the phase difference of 270 degrees is at a high level.

The signal processing circuit 250 obtains, for example, a distance for every pixel on the basis of the count values CNT0 and CNT1 by the following equation.

d=(c/4πf)×tan⁻¹×(CNT1/CNT0) Equation 1

In the above equation, “d” is a distance, and the unit is, for example, meter (m). “c” is a velocity of light, and the unit is, for example, meter per second (m/s). “tan⁻¹” is an inverse function of a tangent function. The value of CNT1/CNT0 indicates a phase difference between the irradiation light and the reflected light. “π” indicates a circular constant. Furthermore, “f” is frequency of the irradiation light, and the unit is, for example, megahertz (MHz).

In this manner, a distance measurement method for calculating distances on the basis of the flight time of light is called a time of flight (ToF) method.

Here, a solid-state imaging element that counts the number of pulses (photons) only by up counting without using up-down counters to perform distance measurement by a ToF method is assumed as a comparative example.

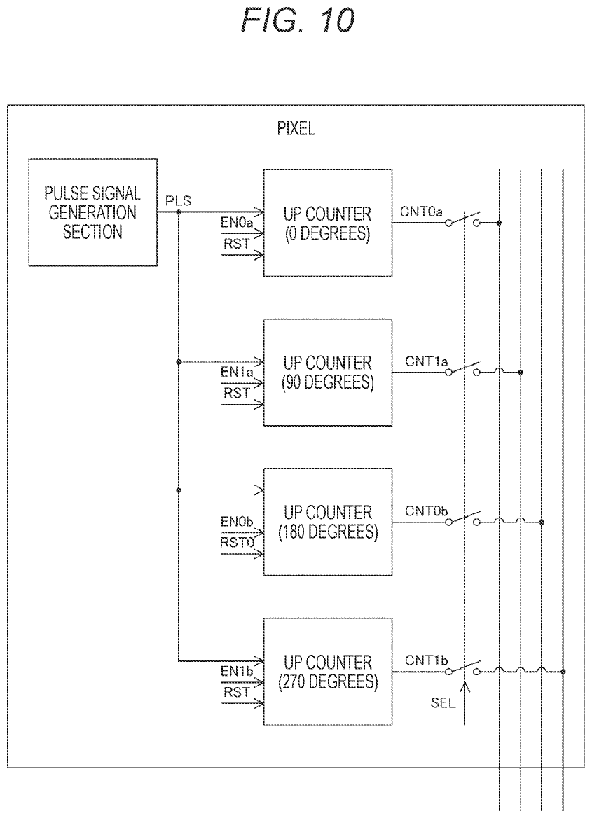

FIG. 10 is a block diagram depicting a configuration example of a pixel in the comparative example. As illustrated in the drawing, in the comparative example, two up counters are required instead of the up-down counter 400. One of these up counters performs up counting during a period in which an enable signal EN0a having a phase difference of 0 degrees is at a high level. The other counter performs up counting during a period in which an enable signal EN0b having a phase difference of 180 degrees is at a high level.

Furthermore, in the comparative example, two up counters are required instead of the up-down counter 401. One of these up counters performs up counting during a period in which an enable signal EN1a having a phase difference of 90 degrees is at a high level. The other counter performs up counting during a period in which an enable signal EN1b having a phase difference of 270 degrees is at a high level.

A signal processing circuit of the comparative example calculates a difference between a count value CNT0a of the counter corresponding to 0 degrees and a count value CNT0b of the counter corresponding to 180 degrees as CNT0. Furthermore, the signal processing circuit of the comparative example calculates a difference between a count value CNT1a of the counter corresponding to 90 degrees and a count value CNT1b of the counter corresponding to 270 degrees as CNT1. Then, the signal processing circuit performs distance measurement by Equation 1.

As illustrated at the same time, it is necessary to provide four up counters for every pixel in the comparative example. On the other hand, in the solid-state imaging element 200 using the up-down counters, the number of counters for each pixel is only two of the up-down counters 400 and 401. Accordingly, the circuit scale of the pixel can be reduced as compared with the comparative example. Therefore, miniaturization of pixels is facilitated.

Furthermore, in the comparative example, there is a possibility that the counters overflow when the brightness of the incident light is high, but the overflow can be suppressed by using the up-down counters 400 and 401. Therefore, a dynamic range of the depth map can be expanded.

Moreover, by performing up counting and down counting by the up-down counters 400 and 401, a common-mode rejection ratio (CMRR) can be improved as compared with the comparative example.

Furthermore, in the comparative example, in order to obtain the difference, memories (two frame memories or the like) that hold the count values CNT0a and CNT1a for every pixel in the circuit at the subsequent stage are required. On the other hand, in the configuration using the up-down counters 400 and 401, these memories are unnecessary. Therefore, the area of the solid-state imaging element 200 can be reduced.

Furthermore, in the comparative example, it is necessary to supply the enable signals EN0a, EN0b, EN1a, and EN1b for every row, so that four wires for transmitting these signals are required. On the other hand, in the configuration using the up-down counters 400 and 401, it is sufficient if only two of the up enable signals UpEN0 and UpEN1 are supplied for every row. Accordingly, the number of wires for transmitting these signals can be reduced to two. Therefore, charge/discharge capacity of the wires can be reduced.

[Operation Example of Sensing System]

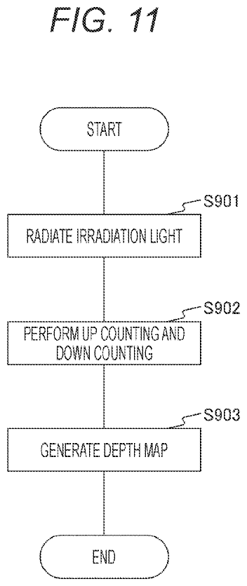

FIG. 11 is a flowchart depicting an example of an operation of the sensing system 100 in the first embodiment of the present technology. The operation is, for example, started when a predetermined application for performing distance measurement is executed.

The light-emitting section 110 radiates irradiation light in synchronization with the light emission control signal LCLK (step S901). Furthermore, the up-down counters 400 and 401 perform up counting and down counting in accordance with the up enable signals (step S902). Then, the signal processing circuit 250 performs distance measurement on the basis of the respective count values of the up-down counters 400 and 401, and generates a depth map (step S903). Then, the sensing system 100 ends the operation for the distance measurement.

Note that, in a case where a plurality of depth maps is continuously generated, steps S901 to S903 are repeatedly executed in synchronization with the vertical synchronization signal VSYNC.

In this manner, in the first embodiment of the present technology, the up-down counters 400 and 401 perform up counting during periods in which the phase differences are 0 degrees and 90 degrees, and perform down counting during periods in which the phase differences are 180 degrees and 270 degrees. Therefore, the number of counters can be reduced from four to two as compared with a case where only up counting is performed during each of the periods in which the phase differences are 0 degrees, 90 degrees, 180 degrees, and 270 degrees. Therefore, the circuit scale for each pixel of the solid-state imaging element 200 can be reduced.

[First Modification]

In the first embodiment described above, avalanche multiplication is performed by the SPADs 311, but general photodiodes that do not perform avalanche multiplication can also be used. The solid-state imaging element 200 of a first modification of the first embodiment is different from that of the first embodiment in that photodiodes that do not perform avalanche multiplication are used.

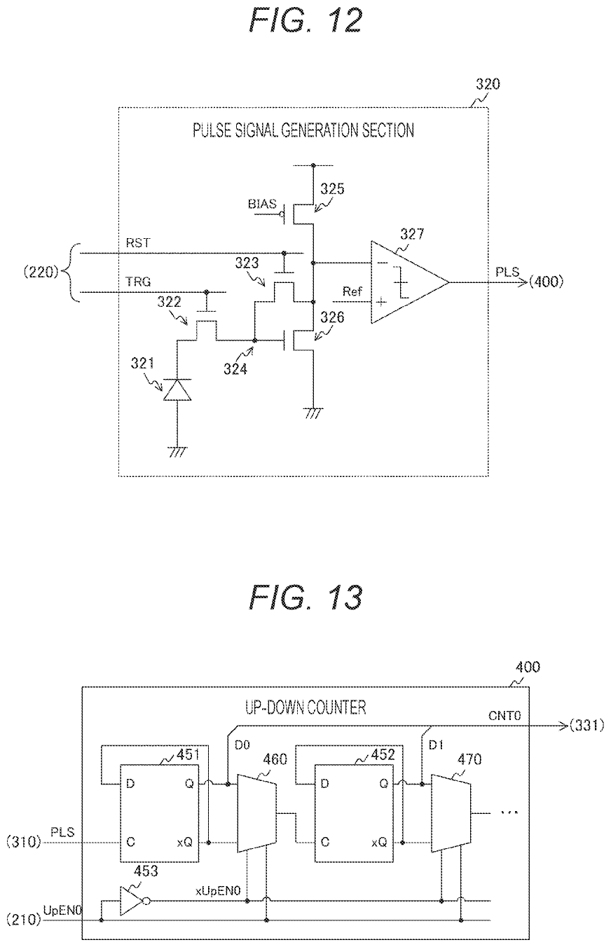

FIG. 12 is a circuit diagram depicting a configuration example of a pulse signal generation section 320 in the first modification of the first embodiment of the present technology. In the first modification of the first embodiment, the pulse signal generation section 320 is arranged for every pixel instead of the pulse signal generation section 310.

The pulse signal generation section 320 includes a photoelectric conversion element 321, a transfer transistor 322, a reset transistor 323, a floating diffusion layer 324, a current source transistor 325, an amplification transistor 326, and a comparator 327.

The photoelectric conversion element 321 is one that converts incident light into a charge. A photodiode that does not perform avalanche multiplication is used as the photoelectric conversion element 321

The transfer transistor 322 is one that transfers the charge from the photoelectric conversion element 321 to the floating diffusion layer 324 in accordance with a transfer signal TRG from the vertical scanning circuit 220.

The reset transistor 323 is one that initializes the floating diffusion layer 324 in accordance with a reset signal RST from the vertical scanning circuit 220.

The current source transistor 325 is one that supplies a current corresponding to a bias voltage BIAS.

The amplification transistor 326 is one that amplifies a voltage of the floating diffusion layer 324. The current source transistor 325 and the amplification transistor 326 are connected in series to a power supply.

A non-inverted input terminal (−) of the comparator 327 is connected to a connection node between the current source transistor 325 and the amplification transistor 326. A predetermined reference signal Ref is input to a non-inverted input terminal (+) of the comparator 327. The comparison result of the comparator 327 is output to the up-down counter 400 and the like as a pulse signal PLS.

As illustrated in the drawing, even with the circuit that does not use the SPAD, one photon or a plurality of photons can be detected by increasing the gain.

In this manner, according to the first modification of the first embodiment of the present technology, the pulse signal generation section 320 detects photons by using a general photodiode (photoelectric conversion element 321). Accordingly, the solid-state imaging element 200 can count the number of photons without using the SPADs.

[Second Modification]

In the first embodiment described above, the up-down counters 400 and 401 are implemented by the JK flip-flops and the selectors, but D flip-flops can also be used instead of the JK flip-flops. The solid-state imaging element 200 of a modification of the first embodiment is different from that of the first embodiment in that D flip-flops are used instead of the JK flip-flops.

FIG. 13 is a circuit diagram depicting a configuration example of the up-down counter 400 in a second modification of the first embodiment of the present technology. The up-down counter 400 includes a plurality of stages of D flip-flops such as D flip-flops 451, 452, and the like, a predetermined number of stages of selectors such as selectors 460, 470, and the like, and an inverter 453. Assuming that the bit depth of a digital signal indicating the coefficient value CNT0 is N, the number of stages of the D flip-flops is N, and the number of stages of the selectors is N−1. Note that the D flip-flops 451 and 452 are examples of first and second flip-flops described in the claims.

Each of the D flip-flops is provided with a delay (D) terminal, a clock (C) terminal, a Q terminal, and an xQ terminal. Each of the selectors is provided with two input terminals and one output terminal.

A pulse signal PLS from the pulse signal generation section 310 is input to the C terminal of the JK flip-flop 451 of the first stage. A non-inverted output signal from the Q terminal of the D flip-flop of the n-th stage and an inverted output signal from the xQ terminal of the D flip-flop of the n-th stage are input to the selector of the n-th stage. Furthermore, the non-inverted output signal of the n-th stage is output to the switch 331 as the n-th bit data Dn of the digital signal indicating the count value CNT0. The inverted output signal of the n-th stage is input to the D terminal of the D flip-flop of the n-th stage.

The inverter 453 is one that inverts the up enable signal UpEN0 and outputs the inverted signal.

The selector of the n-th stage selects either the non-inverted output signal or the inverted output signal of the JK flip-flop of the n-th stage in accordance with the up enable signal UpEN0 and the inverted signal from the inverter 453. The selector of the n-th stage supplies the selected signal to the clock terminal of the JK flip-flop of the (n+1)-th stage as a selection signal.

Note that the circuit configuration of the up-down counter 401 is similar to that of the up-down counter 400.

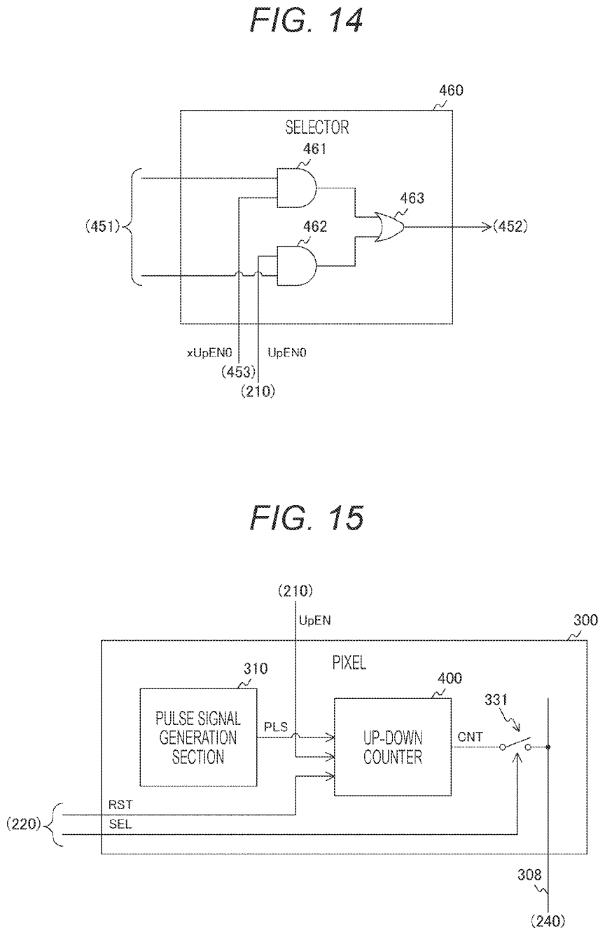

FIG. 14 is a circuit diagram depicting a configuration example of the selector 460 in the second modification of the first embodiment of the present technology. The selector 460 includes AND gates 461 and 462, and an OR gate 463.

The AND gate 461 is one that outputs a logical product of the non-inverted output signal from the Q terminal of the D flip-flop 451 and the inverted signal xUpEN0 from the inverter 453 to the OR gate 463.

The AND gate 462 is one that outputs a logical product of the up enable signal UpEN0 from the pixel driving section 210 and the inverted output signal from the xQ terminal of the D flip-flop 451 to the OR gate 463. The OR gate 463 is one that outputs a logical sum of the signals from the AND gates 461 and 462 to the C terminal of the D flip-flop 452 as a selection signal.

Note that the circuit configuration of the selector 470 is similar to that of the selector 460.

In this manner, in the second modification of the first embodiment of the present technology, the D flip-flop 451 and the like are arranged in the up-down counters 400 and 401. Accordingly, these counters can count the number of photons without using the JK flip-flops.

### 2. Second Embodiment

In the first embodiment described above, two up-down counters are arranged for every pixel, but with this configuration, there is a possibility that it is difficult to miniaturize the pixels. The solid-state imaging element 200 of a second embodiment is different from that of the first embodiment in that the up-down counters are further reduced.

FIG. 15 is a block diagram depicting a configuration example of the pixel 300 in the second embodiment of the present technology. The pixel 300 of the second embodiment is different from that of the first embodiment in that the up-down counter 401 and the switch 332 are not arranged.

Furthermore, a reset signal RST and an up enable signal UpEN are input to the up-down counter 400 of the second embodiment. Furthermore, a count value CNT is output from the up-down counter 400.

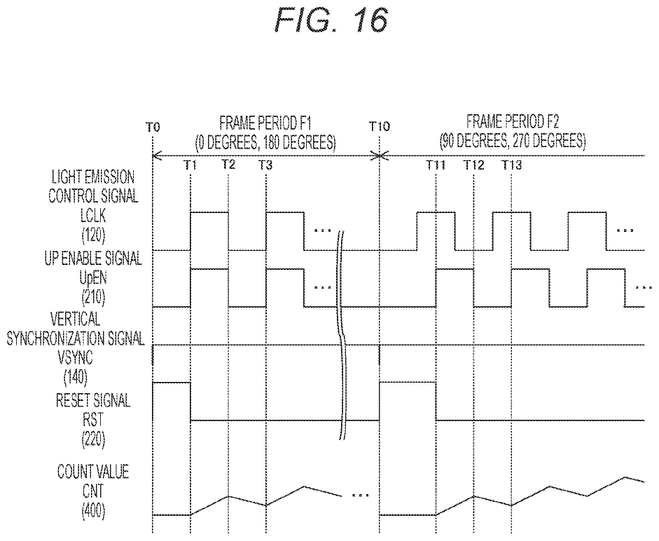

FIG. 16 is a timing chart depicting an example of an operation of the solid-state imaging element 200 in the second embodiment of the present technology. The solid-state imaging element 200 of the second embodiment measures a distance every two frames. For example, in a frame period F1 for imaging a certain frame, the pixel driving section 210 sets the phase difference of the up enable signal UpEN from the light emission control signal LCLK to 0 degrees.

The processor 140 supplies the vertical synchronization signal VSYNC at timings TO and T10.

The pixel driving section 210 supplies the reset signal RST of a high level from a timing T0 at which the frame period F1 starts to a timing T1 at which the light emission control signal LCLK rises. Note that the timing at which the initialization starts is not limited to the timing T0 at which the frame period F1 starts, and can be set to any timing during the frame period F1.

The up-down counter 400 performs up counting with respect to the count value CNT every time the pulse signal PLS is input during a period from the timing T1 to T2 in which the up enable signal UpEN is at a high level. Furthermore, the up-down counter 400 performs down counting every time the pulse signal PLS is input during a period from the timing T2 to T3 in which the up enable signal UpEN is at a low level. Hereinafter, similarly, the up-down counter 400 performs up counting or down counting in accordance with the up enable signal UpEN until the end of the exposure period.

In the next frame period F2, the pixel driving section 210 sets the phase difference of the up enable signal UpEN from the light emission control signal LCLK to 90 degrees.

The pixel driving section 210 supplies the reset signal RST of a high level from a timing T10 at which the frame period F2 starts to a timing T11 at which the up enable signal UpEN rises.

The up-down counter 400 performs up counting every time the pulse signal PLS is input during a period from the timing T11 to T12 in which the up enable signal UpEN is at a high level. Furthermore, the up-down counter 400 performs down counting every time the pulse signal PLS is input during a period from the timing T12 to T13 in which the up enable signal UpEN is at a low level. Hereinafter, similarly, the up-down counter 400 performs up counting or down counting in accordance with the up enable signal UpEN until the end of the exposure period.

By the control illustrated in the drawing, during the frame period F1, the up-down counter 400 obtains the difference between the count value corresponding to the phase difference of 0 degrees and the count value corresponding to the phase difference of 180 degrees. During the next frame period F2, the up-down counter 400 obtains the difference between the count value corresponding to the phase difference of 90 degrees and the count value corresponding to the phase difference of 270 degrees. The up-down counter 400 outputs the difference during the frame period F1 as CNT0, and outputs the difference during the frame period F2 as CNT1. The signal processing circuit 250 obtains the distance for every pixel on the basis of these count values CNT0 and CNT1 by Equation 1.

As described above, in the second embodiment, the phase difference of the up enable signal UpEN is changed between the frame periods F1 and F2. Accordingly, only one up-down counter is required for each pixel. Therefore, the circuit scale for each pixel can be reduced. Furthermore, it is sufficient if the pixel driving section 210 supplies only the up enable signal UpEN for every row. Accordingly, the number of wires for transmitting the signal can be reduced as compared with a case where the up enable signals UpEN0 and UpEN1 are supplied.

Note that the first modification and the second modification of the first embodiment can also be applied to the second embodiment.

In this manner, according to the second embodiment of the present technology, the phase difference of the up enable signal UpEN is changed between the frame periods F1 and F2. Accordingly, the up-down counters and the wires can be reduced as compared with the first embodiment.

### 3. Third Embodiment

In the first embodiment described above, the sensing system 100 performs distance measurement by using the ToF method, but can perform distance measurement by using a structured illumination method instead of the ToF method. The sensing system 100 of a fourth embodiment is different from that of the first embodiment in that the sensing system 100 radiates structured light, and performs distance measurement by using the structured illumination method.

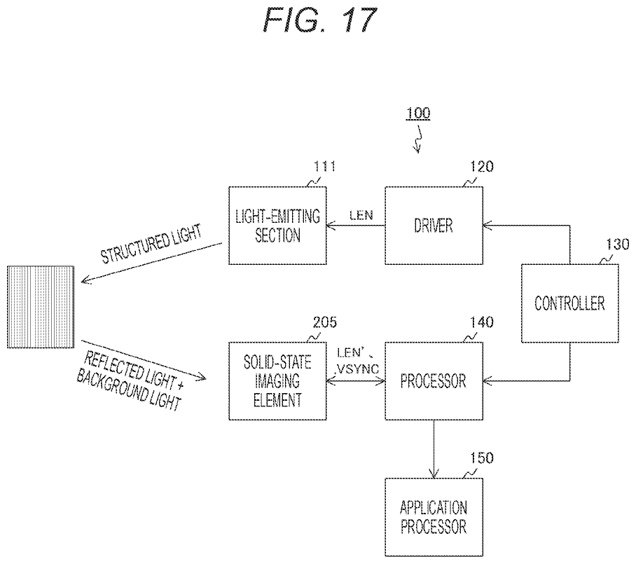

FIG. 17 is a block diagram depicting a configuration example of the sensing system 100 in a third embodiment of the present technology. The sensing system 100 of the third embodiment is different from that of the first embodiment in that the sensing system 100 includes a light-emitting section 111 and a solid-state imaging element 205 instead of the light-emitting section 110 and the solid-state imaging element 200.

The light-emitting section 111 radiates structured light instead of intermittent light in accordance with a light emission control signal LEN from the driver 120. The structured light is continuous light of a specific pattern (a stripe pattern, a grid, or the like) having a constant cycle structure. Incident light including reflected light of the structured light and other background light is incident on the solid-state imaging element 200. Furthermore, the light-emitting section 111 and the driver 120 are arranged, for example, in a projector.

Furthermore, the solid-state imaging element 205 extracts the reflected light from the incident light, and measures a distance by the structured illumination method on the basis of the reflected light. The configuration of the pixel 300 in the solid-state imaging element 205 is similar to that of the second embodiment, and only the up-down counter 400 is arranged as a counter.

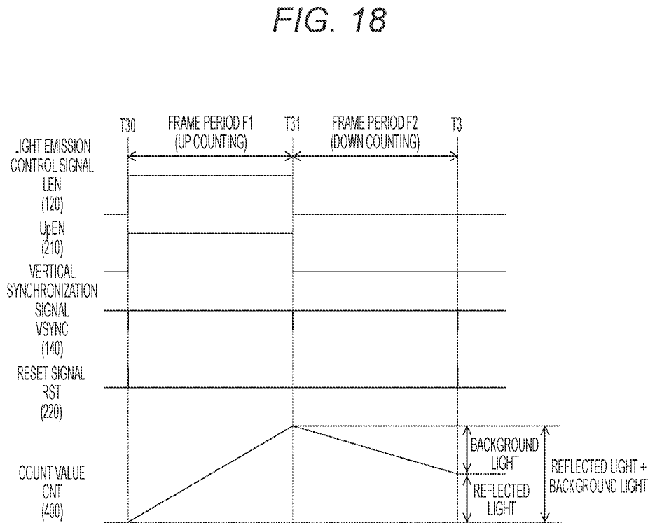

FIG. 18 is a timing chart depicting an example of an operation of the solid-state imaging element 200 in the third embodiment of the present technology. The solid-state imaging element 200 of the second embodiment measures a distance every two frames. For example, in the frame period F1 for imaging a certain frame, the driver 120 sets the light emission control signal LEN to a high level, and makes the light-emitting section 111 radiate the structured light.

Furthermore, in the frame period F1 (in other words, a light-on period of the light-emitting section 111), the up enable signal UpEN is set to a high level. The processor 140 supplies the vertical synchronization signal VSYNC at timings T30, T31, and T32.

At the timing T30 at which the frame period F1 starts, the pixel driving section 210 supplies the reset signal RST. The up-down counter 400 performs up counting every time the pulse signal PLS is input during a period from the timing T30 to T31 in which the up enable signal UpEN is at a high level.

In the next frame period F2. the driver 120 sets the light emission control signal LEN to a low level, and turns off the light-emitting section 111.

Furthermore, in the frame period F2 (in other words, a light-off period of the light-emitting section 111), the up enable signal UpEN is set to a low level. The up-down counter 400 performs down counting every time the pulse signal PLS is input during a period from the timing T31 to T32 in which the up enable signal UpEN is at a low level.

In the control described above, the reflected light of the structured light and the background light are incident on the solid-state imaging element 205 during the frame period F1 (light-on period), and only the background light is incident on the solid-state imaging element 205 during the frame period F2 (light-off period). Furthermore, the up-down counter 400 performs up counting during the light-on period, and performs down counting during the light-off period. The count value during the light-on period is proportional to the light amount of the incident light including the reflected light and the background light, and the count value during the light-off period is proportional to the light amount of only the background light. Accordingly, a difference therebetween indicates the light amount of the reflected light.

Accordingly, the up-down counter 400 can extract only the reflected light of the structured light. The signal processing circuit 250 analyzes a change in the pattern of the structured light. The pattern changes due to moire or the like according to the distance to the object irradiated with the structured light. Accordingly, the signal processing circuit 250 can obtain the distance on the basis of the change. In this manner, the method of radiating the structured light and performing distance measurement on the basis of the change in the pattern is referred to as the structured illumination method. In the structured illumination method, the blinking cycle of the light-emitting section 111 is on the order of microseconds (μs) to milliseconds (ms), and it is not necessary to blink on the order of nanoseconds (ns) as in the ToF method.

Furthermore, a comparative example in which the solid-state imaging element performs up counting in both the light-on period and the light-off period is assumed. In the comparative example, in order to obtain the difference, it is necessary to add a frame memory that holds frames during the light-on period. On the other hand, in the configuration in which the solid-state imaging element 205 performs up counting in the light-on period, and performs down counting in the light-off period, the frame memory is unnecessary.

Note that the up-down counter 400 performs up counting during the light-on period, and performs down counting during the light-off period, but the up-down counter 400 can perform down counting during the light-on period, and can perform up counting during the light-off period.

Furthermore, the first modification and the second modification of the first embodiment can also be applied to the third embodiment.

In this manner, according to the third embodiment of the present technology, the up-down counter 400 performs up counting during the light-on period in which the structured light is radiated, and performs down counting during the light-off period. Accordingly, it is possible to extract only the reflected light of the structured light. Therefore, the signal processing circuit 250 can perform distance measurement by using the structured illumination method.

### 4. Fourth Embodiment

In the first embodiment described above, two up-down counters are arranged for every pixel, but with this configuration, there is a possibility that it is difficult to miniaturize the pixels. The solid-state imaging element 200 of a fourth embodiment is different from that of the first embodiment in that the circuit scale per pixel is reduced.

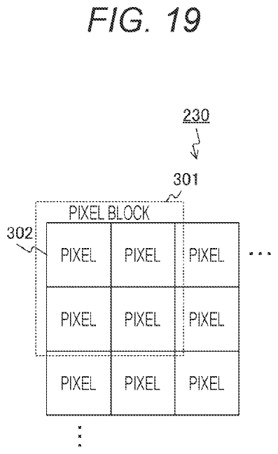

FIG. 19 is a plan view depicting a configuration example of the pixel array section 230 in the fourth embodiment of the present technology. A plurality of pixels 302 is arrayed in the pixel array section 230 of the fourth embodiment. Furthermore, the pixel array section 230 is divided by a plurality of pixel blocks 301. A plurality of pixels 302 is arrayed in each pixel block 301. For example, four pixels 302 of two rows×two columns are arrayed for every pixel block 301.

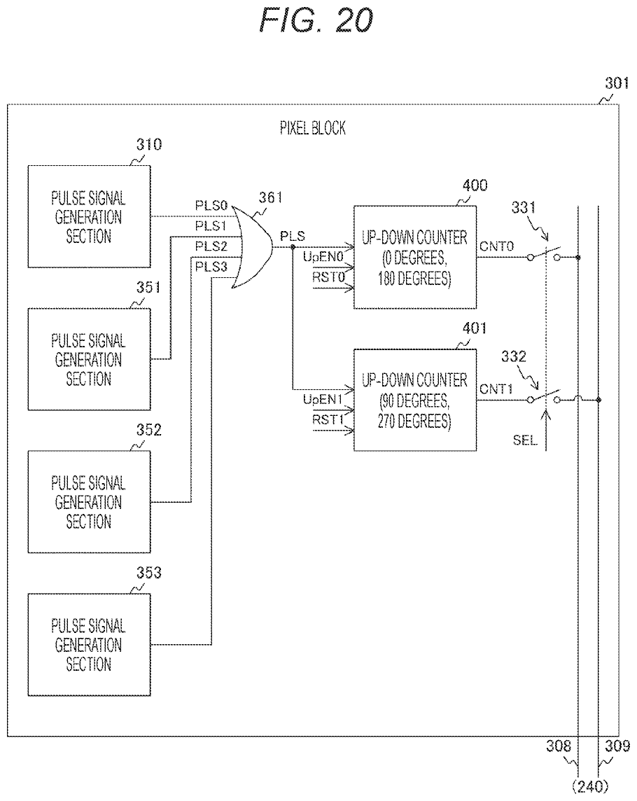

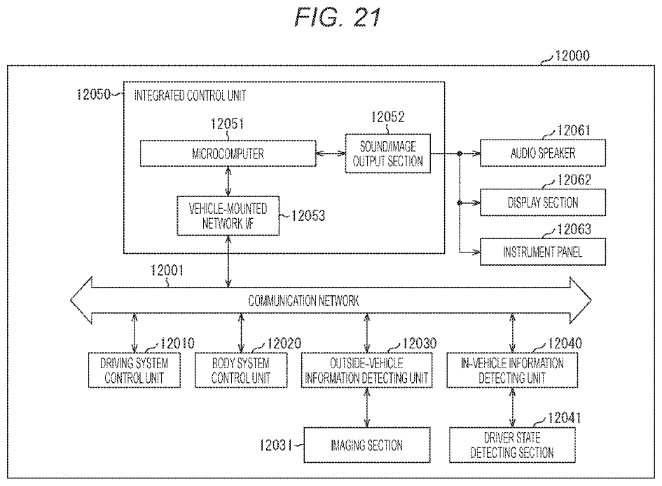

FIG. 20 is a block diagram depicting a configuration example of the pixel block 301 in the fourth embodiment of the present technology. The pixel block 301 includes pulse signal generation sections 310, 351, 352, and 353, a logical sum (OR) gate 361, the up-down counters 400 and 401, and the switches 331 and 332.

Each of the configurations of the pulse signal generation sections 310, 351, 352, and 353 of the fourth embodiment is similar to that of the pulse signal generation section 310 of the first embodiment. The configurations of the up-down counters 400 and 401 and the switches 331 and 332 of the fourth embodiment are similar to those of the first embodiment. Furthermore, the vertical signal lines 308 and 309 are wired for every column of the pixel block 301.

The OR gate 361 is one that supplies a logical sum of pulses PLS0, PLS1, PLS2, and PLS3 from the pulse signal generation sections 310, 351, 352, and 353 to the up-down counters 400 and 401 as a PLS. The OR gate 361 outputs the logical sum of the pulse signals of the four pixels.

The signal processing circuit 250 at the subsequent stage obtains a distance for every pixel block 301 by Equation 1. As illustrated in the drawing, by arranging the up-down counters 400 and 401 for every four pixels, the circuit scale per pixel can be reduced as compared with a case where the up-down counters 400 and 401 are arranged for every pixel.

Note that the first modification and the second modification of the first embodiment, or the second embodiment can also be applied to the fourth embodiment.

In this manner, in the fourth embodiment according to the present technology, the up-down counters 400 and 401 are arranged for every four pixels. Accordingly, the circuit scale per pixel can be reduced as compared with a case where the up-down counters 400 and 401 are arranged for every pixel.

### 5. Application Example to Mobile Body

The technology according to the present disclosure (present technology) can be applied to various products. For example, the technology according to the present disclosure may be implemented as a device included in any type of mobile body such as an automobile, an electric vehicle, a hybrid electric vehicle, a motorcycle, a bicycle, a personal mobility, an airplane, a drone, a ship, a robot, or the like.

FIG. 21 is a block diagram depicting an example of a schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 21, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 21, an audio speaker 12061, a display section 12062, and an instrument panel 12063 are illustrated as the output device. The display section 12062 may, for example, include at least one of an on-board display and a head-up display.

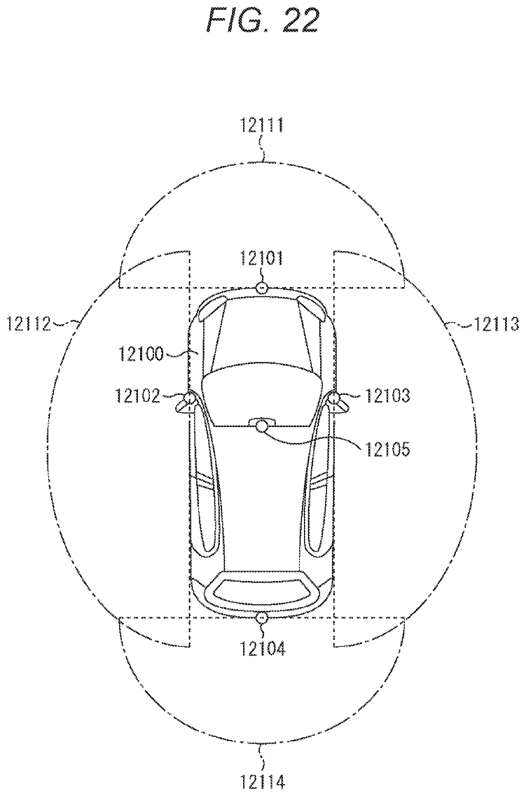

FIG. 22 is a diagram depicting an example of the installation position of the imaging section 12031.

In FIG. 22, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of a vehicle 12100 as well as a position on an upper portion of a windshield within the interior of the vehicle, and the like. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 22 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technology according to the present disclosure can be applied has been described above. The technology according to the present disclosure can be applied to, for example, the imaging section 12031 among the configurations described above. Specifically, the solid-state imaging element 200 in FIG. 3 can be applied to the imaging section 12031. By applying the technology according to the present disclosure to the imaging section 12031, the circuit scale can be reduced when distance measurement is performed.

Note that the embodiments described above illustrate examples for embodying the present technology, and the matters in the embodiments have corresponding relations to the invention specifying matters in the claims, respectively. Similarly, the invention specifying matters in the claims have corresponding relations to the matters in the embodiments of the present technology denoted with the same names as the invention specifying matters, respectively. However, the present technology is not limited to the embodiments, and thus various modifications are made to the embodiments without departing from the scope of the gist so that the present technology can be embodied.

Note that the advantageous effects described in the present specification are merely examples and are not limited, and there may be other advantageous effects.

Note that the present technology can also have the following configurations.

(1) A solid-state imaging element including:

a pulse signal generation section that is provided with an avalanche photodiode that converts incident light including reflected light of irradiation light radiated during a predetermined light-on period into a photocurrent and multiplies the photocurrent and a quench circuit that generates a pulse signal on the basis of the multiplied photocurrent; and

an up-down counter that performs one of up counting and down counting each time the pulse signal is generated during the light-on period, and performs another of the up counting and the down counting each time the pulse signal is generated during a light-off period that does not correspond to the light-on period.

(2) The solid-state imaging element according to the (1),

in which the irradiation light includes intermittent light.

(3) The solid-state imaging element according to the (2),

in which the up-down counter includes first and second up-down counters,

the first up-down counter performs either the up counting or the down counting on the basis of a first clock signal having a phase difference of 0 degrees or 180 degrees from the intermittent light, and

the second up-down counter performs either the up counting or the down counting on the basis of a second clock signal having a phase difference of 90 degrees or 270 degrees from the intermittent light.

(4) The solid-state imaging element according to the (2),

in which the up-down counter performs either the up counting or the down counting on the basis of a predetermined clock signal, and

a phase difference of the clock signal with respect to the intermittent light is set to 0 degrees or 180 degrees during a first period, and set to 90 degrees or 270 degrees during a second period.

(5) The solid-state imaging element according to any one of the (2) to (4), further including

a logical sum gate that supplies a logical sum of the pulse signals of each of a plurality of pixels to the up-down counter,

in which the pulse signal generation section is arranged in each of the plurality of pixels.

(6) The solid-state imaging element according to the (1),

in which the irradiation light includes structured light, and

the incident light includes the reflected light and background light.

(7) The solid-state imaging element according to any one of the (1) to (6),

in which the up-down counter includes:

a first flip-flop to which the pulse signal is input;

a selector that selects either a non-inverted output signal or an inverted output signal of the first flip-flop in accordance with a predetermined enable signal, and outputs the selected signal as a selection signal; and

a second flip-flop to which the selection signal is input.

(8) The solid-state imaging element according to the (7),

in which the first and second flip-flops include JK flip-flops, and

the pulse signal and the selection signal are input to clock terminals.

(9) The solid-state imaging element according to the (7),

in which the first and second flip-flops include D flip-flops,

the pulse signal and the selection signal are input to clock terminals, and

the inverted output signal of the first flip-flop is input to a delay terminal of the first flip-flop.

(10) A sensing system including:

a light-emitting section that radiates irradiation light during a predetermined light-on period;

a pulse signal generation section that is provided with an avalanche photodiode that converts incident light including reflected light of the irradiation light into a photocurrent and multiplies the photocurrent and a quench circuit that generates a pulse signal on the basis of the multiplied photocurrent; and

an up-down counter that performs one of up counting and down counting each time the pulse signal is generated during the light-on period, and performs another of the up counting and the down counting each time the pulse signal is generated during a light-off period that does not correspond to the light-on period.

(11) A control method of a solid-state imaging element including:

a pulse signal generation procedure of converting incident light including reflected light of irradiation light radiated during a predetermined light-on period into a photocurrent and multiplying the photocurrent, and generating a pulse signal on the basis of the multiplied photocurrent; and

an up-down counting procedure in which an up-down counter performs one of up counting and down counting each time the pulse signal is generated during the light-on period, and performs another of the up counting and the down counting each time the pulse signal is generated during a light-off period that does not correspond to the light-on period.

### REFERENCE SIGNS LIST

100 Sensing system
110, 111 Light-emitting section
120 Driver
130 Controller
140 Processor
150 Application processor
200, 205 Solid-state imaging element
201 Pixel chip
202 Circuit chip
210 Pixel driving section
220 Vertical scanning circuit
230 Pixel array section
240 Column buffer
250 Signal processing circuit
260 Output section
300, 302 Pixel
301 Pixel block
310, 320, 351 to 353 Pulse signal generation section
311 SPAD
312 Quench circuit
313 Resistor
314 Inverter
321 Photoelectric conversion element
322 Transfer transistor
323 Reset transistor
324 Floating diffusion layer
325 Current source transistor
326 Amplification transistor
327 Comparator
331, 332 Switch
361, 424, 463 Logical sum (OR) gate
400, 401 Up-down counter
411, 412 JK flip-flop
420, 430, 460, 470 Selector
421, 453 Inverter
422, 423, 461, 462 Logical product (AND) gate
451, 452 D flip-flop
12031 Imaging section

1. A solid-state imaging element comprising:
a pulse signal generation section that is provided with an avalanche photodiode that converts incident light including reflected light of irradiation light radiated during a predetermined light-on period into a photocurrent and multiplies the photocurrent and a quench circuit that generates a pulse signal on a basis of the multiplied photocurrent; and
an up-down counter that performs one of up counting and down counting each time the pulse signal is generated during the light-on period, and performs another of the up counting and the down counting each time the pulse signal is generated during a light-off period that does not correspond to the light-on period.

2. The solid-state imaging element according to claim 1,
wherein the irradiation light includes intermittent light.

3. The solid-state imaging element according to claim 2,
wherein the up-down counter includes first and second up-down counters,
the first up-down counter performs either the up counting or the down counting on a basis of a first clock signal having a phase difference of 0 degrees or 180 degrees from the intermittent light, and
the second up-down counter performs either the up counting or the down counting on a basis of a second clock signal having a phase difference of 90 degrees or 270 degrees from the intermittent light.

4. The solid-state imaging element according to claim 2,
wherein the up-down counter performs either the up counting or the down counting on a basis of a predetermined clock signal, and
a phase difference of the clock signal with respect to the intermittent light is set to 0 degrees or 180 degrees during a first period, and set to 90 degrees or 270 degrees during a second period.

5. The solid-state imaging element according to claim 2, further comprising
a logical sum gate that supplies a logical sum of the pulse signals of each of a plurality of pixels to the up-down counter,
wherein the pulse signal generation section is arranged in each of the plurality of pixels.

6. The solid-state imaging element according to claim 1,
wherein the irradiation light includes structured light, and
the incident light includes the reflected light and background light.

7. The solid-state imaging element according to claim 1,
wherein the up-down counter includes:
a first flip-flop to which the pulse signal is input;
a selector that selects either a non-inverted output signal or an inverted output signal of the first flip-flop in accordance with a predetermined enable signal, and outputs the selected signal as a selection signal; and
a second flip-flop to which the selection signal is input.

8. The solid-state imaging element according to claim 7,
wherein the first and second flip-flops include JK flip-flops, and
the pulse signal and the selection signal are input to clock terminals.

9. The solid-state imaging element according to claim 7,
wherein the first and second flip-flops include D flip-flops,
the pulse signal and the selection signal are input to clock terminals, and
the inverted output signal of the first flip-flop is input to a delay terminal of the first flip-flop.

10. A sensing system comprising:
a light-emitting section that radiates irradiation light during a predetermined light-on period;
a pulse signal generation section that is provided with an avalanche photodiode that converts incident light including reflected light of the irradiation light into a photocurrent and multiplies the photocurrent and a quench circuit that generates a pulse signal on a basis of the multiplied photocurrent; and
an up-down counter that performs one of up counting and down counting each time the pulse signal is generated during the light-on period, and performs another of the up counting and the down counting each time the pulse signal is generated during a light-off period that does not correspond to the light-on period.

11. A control method of a solid-state imaging element comprising:
a pulse signal generation procedure of converting incident light including reflected light of irradiation light radiated during a predetermined light-on period into a photocurrent and multiplying the photocurrent, and generating a pulse signal on a basis of the multiplied photocurrent; and
an up-down counting procedure in which an up-down counter performs one of up counting and down counting each time the pulse signal is generated during the light-on period, and performs another of the up counting and the down counting each time the pulse signal is generated during a light-off period that does not correspond to the light-on period.
